(19) United States
(12) Patent Application Publication
(10) Pub. No.: US 2025/0192727 A1
(43) Pub. Date: Jun. 12, 2025

(54) AMPLIFIER AND DRIVER AMPLIFIER CIRCUIT

(71) Applicant: SUMITOMO ELECTRIC INDUSTRIES, LTD., Osaka (JP)

(72) Inventors: Noriyoshi SUDA, Osaka-shi (JP); Hirotaka ASAMI, Osaka-shi (JP)

(73) Assignee: SUMITOMO ELECTRIC INDUSTRIES, LTD., Osaka (JP)

(21) Appl. No.: 18/955,017

(22) Filed: Nov. 21, 2024

(30) Foreign Application Priority Data
Dec. 7, 2023 (JP) 2023-207182

(51) Int. Cl. H03F 1/02; H03F 1/56; H03F 3/24

(52) U.S. Cl. CPC H03F 1/0288; H03F 1/56; H03F 3/245; H03F 2200/198

(57) ABSTRACT

An amplifier includes a first amplifier circuit, and a second amplifier circuit that amplifies an output signal of the first amplifier circuit. The first amplifier circuit includes a first divider that divides an input signal into a first signal and a second signal, a control amplifier that amplifies the first signal and output an amplified signal as a third signal, a second divider that divide the second signal into a fourth signal and a fifth signal having different phases at a center frequency of an operation band, a first auxiliary amplifier that amplifies the fourth signal and outputs an amplified signal as a sixth signal, a second auxiliary amplifier that amplifies the fifth signal and outputs an amplified signal as a seventh signal, and a hybrid coupler including a first end, a second end, a third end, and a fourth end.

### CROSS REFERENCE TO RELATED APPLICATIONS

This application claims priority based on Japanese Patent Application No. 2023-207182 filed on Dec. 7, 2023, and the entire contents of the Japanese patent application are incorporated herein by reference.

### TECHNICAL FIELD

The present invention relates to an amplifier and a driver amplifier circuit.

### BACKGROUND ART

It is known that a load modulated balanced amplifier (LMBA) is used as a power amplifier at a final stage for transmission in mobile communication (for example, U.S. Patent Application Publication No. 2022/0255506).

### SUMMARY OF THE INVENTION

An amplifier according to an embodiment of the present disclosure includes a first amplifier circuit, and a second amplifier circuit that amplifies an output signal of the first amplifier circuit. The first amplifier circuit includes a first divider that divides an input signal into a first signal and a second signal, a control amplifier that amplifies the first signal and outputs an amplified signal as a third signal, a second divider that divides the second signal into a fourth signal and a fifth signal having different phases at a center frequency of an operation band, a first auxiliary amplifier that amplifies the fourth signal and outputs an amplified signal as a sixth signal, a second auxiliary amplifier that amplifies the fifth signal and outputs an amplified signal as a seventh signal, and a hybrid coupler including a first end that receives the sixth signal, a second end that receives the seventh signal, a third end that receives the third signal, and a fourth end that outputs the output signal.

A driver amplifier circuit according to an embodiment of the present disclosure includes a first divider that divides an input signal into a first signal and a second signal, a control amplifier that amplifies the first signal and outputs an amplified signal as a third signal, a second divider that divides the second signal into a fourth signal and a fifth signal having different phases at a center frequency of an operation band, a first auxiliary amplifier that amplifies the fourth signal and outputs an amplified signal as a sixth signal, a second auxiliary amplifier that amplifies the fifth signal and outputs an amplified signal as a seventh signal, and a hybrid coupler including a first end that receives the sixth signal, a second end that receives the seventh signal, a third end that receives the third signal, and a fourth end that outputs an output signal to a subsequent-stage amplifier circuit.

### BRIEF DESCRIPTION OF THE DRAWINGS

FIG. 1 is a circuit diagram of an amplifier according to a first embodiment.

FIG. 2 is a block diagram illustrating details of a driver amplifier circuit in a first embodiment.

FIG. 3 is a circuit diagram of a branch line coupler used in a divider and a coupler in a first embodiment.

FIG. 4 is a block diagram of a coupler and the vicinity of the coupler in a first embodiment.

FIG. 5 is a block diagram of an amplifier according to a first modification of a first embodiment.

FIG. 6 is a block diagram of an amplifier according to a first comparative example.

FIG. 7 is a block diagram of an amplifier according to a second comparative example.

### DETAILED DESCRIPTION

When the output power of the power amplifier at the final stage changes, the load of the driver amplifier varies. Thus, the characteristics of the driver amplifier are deteriorated.

The present disclosure has been made in view of the above problems, and an object thereof is to improve characteristics.

### Description of Embodiments of Present Disclosure

First, the contents of embodiments of the present disclosure will be listed and explained.

(1) An amplifier according to an embodiment of the present disclosure includes a first amplifier circuit, and a second amplifier circuit that amplifies an output signal of the first amplifier circuit. The first amplifier circuit includes a first divider that divides an input signal into a first signal and a second signal, a control amplifier that amplifies the first signal and outputs an amplified signal as a third signal, a second divider that divides the second signal into a fourth signal and a fifth signal having different phases at a center frequency of an operation band, a first auxiliary amplifier that amplifies the fourth signal and outputs an amplified signal as a sixth signal, a second auxiliary amplifier that amplifies the fifth signal and outputs an amplified signal as a seventh signal, and a hybrid coupler including a first end that receives the sixth signal, a second end that receives the seventh signal, a third end that receives the third signal, and a fourth end that outputs the output signal. By using the hybrid coupler, it is possible to increase the tolerance to load variation seen from the first amplifier circuit toward the second amplifier circuit. In addition, efficiency can be increased. Thus, the characteristics can be improved.

(2) In the above (1), the control amplifier, the first auxiliary amplifier, and the second auxiliary amplifier may perform class-A or class-AB operation. This can improve linearity and efficiency.

(3) In the above (1) or (2), the control amplifier, the first auxiliary amplifier, and the second auxiliary amplifier may have a mutually equal input bias voltage. This makes it possible to reduce the number of bias voltages.

(4) In any one of the above (1) to (3), the second amplifier circuit may include a first amplifier that perform class-A or class-AB operation and a second amplifier connected in parallel to the first amplifier and that perform class-C operation. Thus, although the load variation seen from first amplifier circuit toward the second amplifier circuit increases, the tolerance to the load variation can be improved.

(5) In any one of the above (1) to (3), the second amplifier circuit may be a load modulated balanced amplifier (LMBA) or a Doherty amplifier circuit. Thus, although the load variation seen from the first amplifier circuit toward the second amplifier circuit increases, the tolerance to the load variation can be improved.

(6) In the above (1), the control amplifier, the first auxiliary amplifier, and the second auxiliary amplifier may be perform class-A or class-AB operation, and the second amplifier circuit may be a load modulated balanced amplifier (LMBA) or a Doherty amplifier circuit. Thus, although the load variation seen from the first amplifier circuit toward the second amplifier circuit increases, the tolerance to the load variation can be improved.

(7) In any one of the above (1) to (6), the hybrid coupler may be a branch line coupler. Thus, the tolerance to the load variation can be improved.

(8) A driver amplifier circuit according to an embodiment of the present disclosure includes a first divider that divides an input signal into a first signal and a second signal, a control amplifier that amplifies the first signal and outputs an amplified signal as a third signal, a second divider that divides the second signal into a fourth signal and a fifth signal having different phases at a center frequency of an operation band, a first auxiliary amplifier that amplifies the fourth signal and outputs an amplified signal as a sixth signal, a second auxiliary amplifier that amplifies the fifth signal and outputs an amplified signal as a seventh signal, and a hybrid coupler including a first end that receives the sixth signal, a second end that receives the seventh signal, a third end that receives the third signal, and a fourth end that outputs an output signal to a subsequent-stage amplifier circuit. By using the hybrid coupler, it is possible to increase the tolerance to the load variation seen from the driver amplifier circuit toward the subsequent-stage amplifier circuit. In addition, efficiency can be increased. Thus, the characteristics can be improved.

(9) In the above (8), the control amplifier, the first auxiliary amplifier, and the second auxiliary amplifier may perform class-A or class-AB operation. This can improve linearity and efficiency.

(10) In the above (8) or (9), the control amplifier, the first auxiliary amplifier, and the second auxiliary amplifier may have a mutually equal input bias voltage. This makes it possible to reduce the number of bias voltages.

### DETAILS OF EMBODIMENTS OF PRESENT DISCLOSURE

Specific examples of an amplifier and a driver amplifier circuit according to embodiments of the present disclosure will be described below with reference to the drawings. The present disclosure is not limited to these examples, but is defined by the scope of the claims, and is intended to include all modifications within the meaning and scope equivalent to the scope of the claims.

### First Embodiment

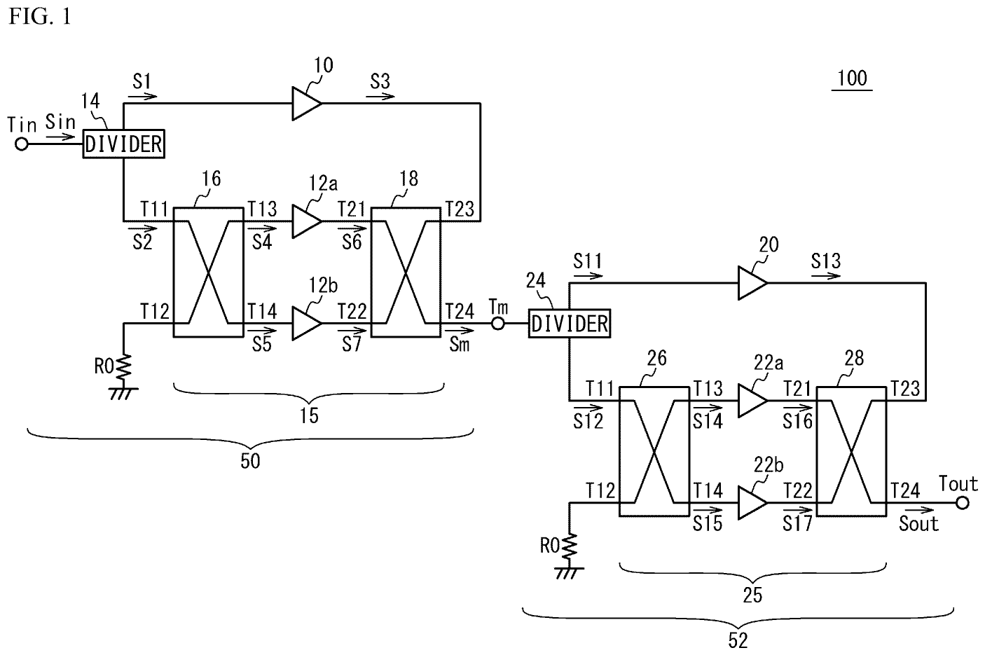

A first embodiment is an example in which an LMBA is used as a driver amplifier circuit and a power amplifier circuit. FIG. 1 is a circuit diagram of an amplifier according to the first embodiment. As illustrated in FIG. 1, in an amplifier 100 of the first embodiment, a driver amplifier circuit 50 is connected to an input terminal Tin and an intermediate terminal Tm, and a power amplifier circuit 52 is connected to intermediate terminal Tm and an output terminal Tout. Driver amplifier circuit 50 (first amplifier circuit) amplifies an input signal Sin, which is a high-frequency signal input to input terminal Tin, and outputs the amplified signal to intermediate terminal Tm as an intermediate signal Sm. Power amplifier circuit 52 (second amplifier circuit, subsequent-stage amplifier circuit) amplifies intermediate signal Sm input to intermediate terminal Tm and outputs the amplified signal to output terminal Tout as an output signal Sout.

When amplifier 100 is used in a base transceiver station for mobile communications, the frequencies of input signal Sin, intermediate signal Sm, and output signal Sout are, for example, 0.5 GHz to 20 GHz. Output signal Sout is radiated from, for example, an antenna into space.

In driver amplifier circuit 50, a control amplifier 10 and a balance amplifier 15 are connected in parallel to input terminal Tin and intermediate terminal Tm. A high-frequency signal is input to input terminal Tin as input signal Sin. A divider 14 (first divider) divides input signal Sin input to input terminal Tin into signals S1 (first signal) and S2 (second signal). Control amplifier 10 amplifies signal S1 and outputs the amplified signal as a signal S3 (third signal) to an end T23 of a coupler 18.

Signal S2 divided by divider 14 is input to balance amplifier 15. Balance amplifier 15 includes a divider 16, auxiliary amplifiers 12a and 12b, and coupler 18. Divider 16 (second divider) divides signal S2 input to an end T11 into signals S4 (fourth signal) and S5 (fifth signal), and outputs the signals from ends T13 and T14, respectively. An end T12 of divider 16 is grounded via a resistor R0 (for example, 50Ω).

Auxiliary amplifier 12a (first auxiliary amplifier) amplifies signal S4 and outputs the amplified signal as a signal S6 (sixth signal) to an end T21 of coupler 18. Auxiliary amplifier 12b (second auxiliary amplifier) amplifies signal S5 and outputs the amplified signal as a signal S7 (seventh signal) to an end T22 of coupler 18. Coupler 18 combines signals S3, S6 and S7, and outputs the combined signal as intermediate signal Sm from an end T24 of coupler 18 to intermediate terminal Tm.

In power amplifier circuit 52, a control amplifier 20 and a balance amplifier 25 are connected in parallel to intermediate terminal Tm and output terminal Tout. A divider 24 divides intermediate signal Sm input to intermediate terminal Tm into signals S11 and S12. Control amplifier 20 amplifies signal S11 and outputs the amplified signal as a signal S13 to end T23 of a coupler 28.

Signal S12 divided by divider 24 is input to balance amplifier 25. Balance amplifier 25 includes a divider 26, auxiliary amplifiers 22a and 22b, and coupler 28. Divider 26 divides signal S12 input to end T11 into signals S14 and S15, and outputs signals S14 and S15 from ends T13 and T14, respectively. End T12 of divider 26 is grounded through resistor R0.

Auxiliary amplifier 22a amplifies signal S14 and outputs the amplified signal as a signal S16 to end T21 of coupler 28. Auxiliary amplifier 22b amplifies signal S15 and outputs the amplified signal as a signal S17 to end T22 of coupler 28. Coupler 28 combines signals S13, S16 and S17 and outputs the combined signal as output signal Sout from end T24 of coupler 28 to output terminal Tout.

### [Detailed Description of Driver Amplifier Circuit]

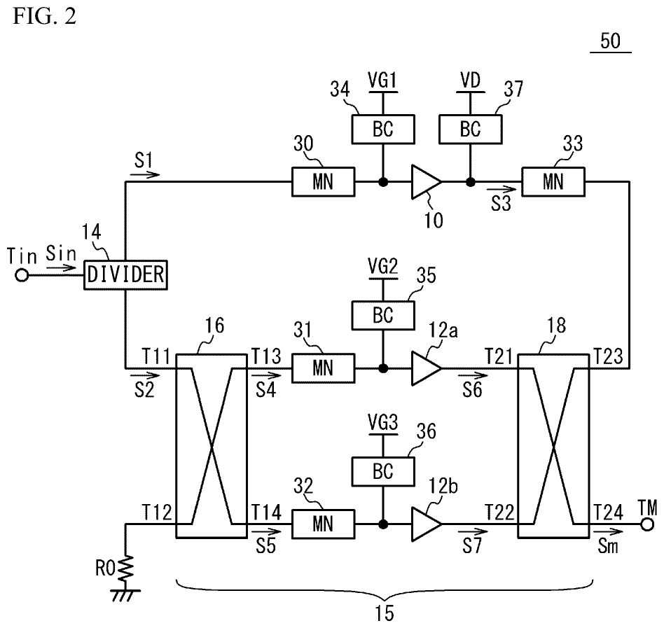

FIG. 2 is a block diagram illustrating details of the driver amplifier circuit in the first embodiment. As illustrated in FIG. 2, signal S1 divided by divider 14 passes through a matching network (MN) 30 and is input to control amplifier 10. Matching network 30 matches the impedance seen from divider 14 toward matching network 30 and the impedance seen from matching network 30 toward control amplifier 10. A bias circuit (BC) 34 is connected to a node in a line between divider 14 and control amplifier 10. Bias circuit 34 supplies an input bias voltage VG1 to control amplifier 10, and makes it difficult for signal S1 from leak to the power supply that supplies input bias voltage VG1.

Signal S3 amplified by control amplifier 10 passes through a matching network 33 and is input to end T23 of coupler 18. Matching network 33 matches the impedance seen from control amplifier 10 toward matching network 33 and the impedance seen from matching network 33 toward coupler 18. A bias circuit 37 is connected to a node in a line between control amplifier 10 and coupler 18. Bias circuit 37 supplies an output bias voltage VD to control amplifier 10, and makes it difficult for signal S3 from leak to the power supply that supplies output bias voltage VD.

Signal S2 divided by divider 14 is input to balance amplifier 15. Balance amplifier 15 includes divider 16, auxiliary amplifiers 12a and 12b, and coupler 18. Divider 16 divides signal S2 input to end T11 into signals S4 and S5, and outputs signals S4 and S5 from ends T13 and T14, respectively. At a center frequency of an operation band, the phase of signal S4 is delayed from the phase of signal S3 by, for example, approximately 90°. The amplitudes of signals S3 and S4 are, for example, substantially the same. The term 90° in the present disclosure does not have to be exactly 90°, but may also be, for example, more than 85° and less than 95°, or 88° to 92°. The same applies to the following examples.

Signal S4 passes through a matching network 31 and is input to auxiliary amplifier 12a. Matching network 31 matches an impedance seen from divider 16 toward matching network 31 and an impedance seen from matching network 31 toward auxiliary amplifier 12a. A bias circuit 35 is connected to a node in a line between divider 16 and auxiliary amplifier 12a. Bias circuit 35 supplies an input bias voltage VG2 to auxiliary amplifier 12a, and makes it difficult for signal S4 to leak to the power supply that supplies input bias voltage VG2. Signal S6 amplified by auxiliary amplifier 12a is input to end T21 of coupler 18.

Signal S5 passes through a matching network 32 and is input to auxiliary amplifier 12b. Matching network 32 matches an impedance seen from divider 16 toward matching network 32 and an impedance seen from matching network 32 toward auxiliary amplifier 12b. A bias circuit 36 is connected to a node in a line between divider 16 and auxiliary amplifier 12b. Bias circuit 36 supplies an input bias voltage VG3 to auxiliary amplifier 12b, and makes it difficult for signal S5 from leak to the power supply that supplies input bias voltage VG3. Signal S7 amplified by auxiliary amplifier 12b is input to end T22 of coupler 18.

A matching network for matching impedance may be connected to the lines between auxiliary amplifiers 12a and 12b and coupler 18. In the first embodiment, coupler 18 adjusts the loads of auxiliary amplifiers 12a and 12b. Thus, a matching network does not have to be provided between auxiliary amplifiers 12a and 12b and coupler 18. A harmonic processing circuit that reflects harmonic signals in signal S6 and S7 may be connected to the lines between auxiliary amplifiers 12a and 12b and coupler 18. The harmonic signal is, for example, a second harmonic or a third harmonic when the operating frequency of the amplifier circuit is a fundamental wave. A bias circuit for supplying an output bias voltage to auxiliary amplifiers 12a and 12b may be provided between auxiliary amplifiers 12a and 12b and coupler 18. In the first embodiment, the output bias voltage of auxiliary amplifiers 12a and 12b is supplied from bias circuit 37 to auxiliary amplifiers 12a and 12b through coupler 18.

Control amplifier 10 and auxiliary amplifiers 12a and 12b are transistors such as field effect transistors (FET), and have sources grounded, gates to which a high-frequency signal is input, and drains from which a high-frequency signal is output. The FET is, for example, a gallium nitride high electron mobility transistor (GaN HEMT) or a laterally diffused metal oxide semiconductor (LDMOS). Control amplifier 10 and auxiliary amplifiers 12a and 12b may each be provided with a multistage FET. When control amplifier 10 and auxiliary amplifiers 12a and 12b are FETs, input bias voltages VG1, VG2, and VG3 are gate bias voltages, and out bias voltage VD is a drain bias voltage.

Control amplifier 10 and auxiliary amplifiers 12a and 12b are class-AB or class-B amplifiers. Input bias voltages VG1, VG2 and VG3 are the same bias voltage. Thus, the operating points of control amplifier 10 and auxiliary amplifiers 12a and 12b are substantially the same when the input power is small. As described above, in driver amplifier circuit 50, control amplifier 10 and auxiliary amplifiers 12a and 12b amplify input signal Sin in parallel from the time when the input power of input signal Sin is small.

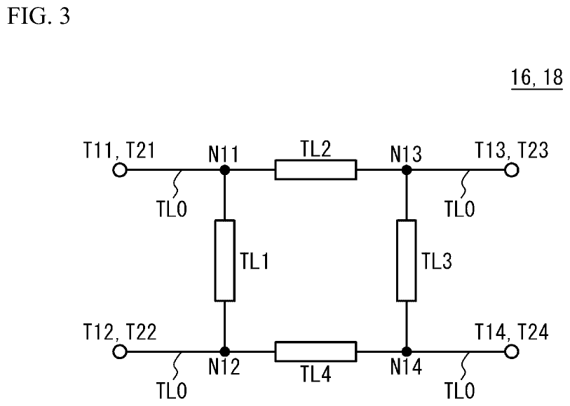

Description of Branch Line Coupler FIG. 3 is a circuit diagram of a branch line coupler used in a divider and a coupler in the first embodiment. As illustrated in FIG. 3, a distributed constant type branch line coupler is used as divider 16 and coupler 18. Transmission line TL1 is connected to nodes N11 and N12, transmission line TL2 is connected to nodes N11 and N13, transmission line TL3 is connected to nodes N13 and N14, and transmission line TL4 is connected to nodes N12 and N14. Transmission lines TL1 to TL4 are λ/4 transmission lines. The electrical length of the λ/4 transmission line is, for example, approximately λ/4. Here, λ is the wavelength of a center frequency fo of the operation band of amplifier 100. The electrical length of the λ/4 transmission line in the present disclosure does not have to be strictly λ/4, and may be, for example, 3λ/16 to 5λ/16, 7λ/32 to 9λ/32, or 15λ/64 to 17λ/64. End T11 or T21 and node N11, end T12 or T22 and node N12, end T13 or T23 and node N13, and end T14 or T24 and node N14 are connected with a transmission line TL0.

In divider 16 of driver amplifier circuit 50, signal S2 input to end T11 is divided into signals S4 and S5, and are output from ends T13 and T14, respectively. The phase of center frequency fo of signal S6 is delayed by approximately 90° from the phase of center frequency fo of signal S5. End T12 is connected to the reference potential through resistor R0. The resistance value of resistor R0 is, for example, a reference impedance (for example, 50Ω). Divider 16 may be, for example, a coupler in which a Wilkinson divider and a λ/4 transmission line are combined, a lumped-constant type branch line coupler using an inductor and a capacitor, a distributed coupling type coupler in which two transmission lines are electromagnetically coupled, or a close-wound coil coupler in which two inductors are electromagnetically coupled.

### [Description of Coupler]

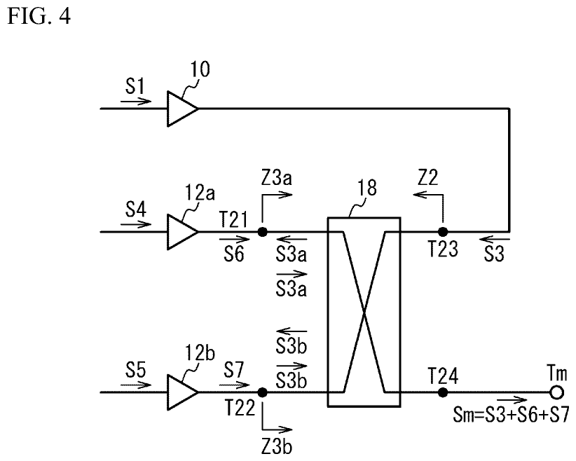

FIG. 4 is a block diagram of a coupler and the vicinity of the coupler in the first embodiment. As illustrated in FIG. 4, in coupler 18 of driver amplifier circuit 50, signal S3 input to coupler 18 from end T23 is divided into two signals S3a and S3b at ends T21 and T22. A ratio of the amplitudes of the powers of signals S3a and S3b is approximately 1:1. The phase of signal S3b at end T22 is delayed by approximately 90° from the phase of signal S3a at end T21. Signals S3a and S3b are reflected at ends T21 and T22, respectively. The phase of signal S7 is delayed by approximately 90° from signal S6. The phase of signal S3b at end T22 is delayed by approximately 90° from signal S3a at end T21. Thus, by appropriately adjusting the phase difference between signals S1 and S2, the phases of signals S6 and S3a at end T21 are matched, and the phases of signals S7 and S3b at end T22 are matched. Signal S6+S3a combined at end T21 and signal S7+S3b combined at end T22 are combined at end T24. The path from end T21 to end T24 is λ/4 longer than the path from end T22 to end T24. Thus, at end T24, the phases of signal S6+S3a and signal S7+S3b are aligned. Combined signal S3+S6+S7 is output to the intermediate terminal Tm as intermediate signal Sm.

The signals incident on ends T21 and T22 from auxiliary amplifiers 12a and 12b are substantially S6+S3a and S7+S3b, respectively, and the signals reflected at ends T21 and T22 are substantially S3a and S3b, respectively. Thus, the reflection coefficients (that is, the absolute values of impedances Z3a and Z3b) seen from auxiliary amplifiers 12a and 12b toward ends T21 and T22 are smaller than 1, and the larger the amplitudes of the powers of signals S6 and S7 are, the smaller the reflection coefficients are. Impedances Z3a and Z3b serving as loads of auxiliary amplifiers 12a and 12b substantially decrease as the amplitudes of the powers of signals S6 and S7 increase. In this way, coupler 18 modulates impedances Z3a and Z3b, which serve as loads seen from auxiliary amplifiers 12a and 12b toward coupler 18, depending on the amplitudes of signals S6 and S7. On the other hand, since signal S6 and S7 are not output from end T23, an impedance Z2 seen from matching network 33 toward end T23 is the reference impedance (for example, 50Ω, which is the characteristic impedance of transmission line TL0) regardless of the magnitudes of the amplitudes of signals S6 and S7. Although the distributed constant type branch line coupler is described as an example of coupler 18, coupler 18 may be a lumped-constant type branch line coupler using an inductor and a capacitor.

### [Description of Power Amplifier Circuit]

In power amplifier circuit 52, control amplifier 20 is a class-A amplifier or a class-AB amplifier, and auxiliary amplifiers 22a and 22b are class-C amplifiers. Input bias voltage VG2 and VG3 are negatively larger than input bias voltage VG1. Thus, the power of intermediate signal Sm at which auxiliary amplifiers 22a and 22b are turned on is larger than the power of the intermediate signal at which control amplifier 20 is turned on. The output power of power amplifier circuit 52 is larger than the output power of driver amplifier circuit 50. Thus, the saturation power of control amplifier 20 and auxiliary amplifiers 22a and 22b is larger than the saturation power of control amplifier 10 and auxiliary amplifiers 12a and 12b of driver amplifier circuit 50.

In power amplifier circuit 52, when the power of intermediate signal Sm is small, control amplifier 20 operates, and auxiliary amplifiers 22a and 22b do not operate. Signal S13 input to coupler 28 from end T23 is divided into two toward ends T21 and T22, and the divided signals are reflected at ends T21 and T22. The reflected signals are combined at end T24, and combined signal S13 is output to output terminal Tout as output signal Sout. In this case, the impedance seen from end T23 toward coupler 28 is the reference impedance.

When the power of intermediate signal Sm is large, auxiliary amplifiers 22a and 22b operate in addition to control amplifier 20. The operation of coupler 28 at this time is the same as that of coupler 18 of driver amplifier circuit 50. A signal obtained by combining signals S13, S16, and S17 is output as output signal Sout to end T24. An impedance seen from end T23 toward coupler 28 is substantially equal to the reference impedance regardless of the power of intermediate signal Sm. An impedance seen from auxiliary amplifiers 22a and 22b toward coupler 28 depends on the magnitude of the power of signals S16 and S17. In this way, coupler 28 modulates the impedance serving as loads seen from auxiliary amplifiers 22a and 22b toward coupler 28, depending on the amplitudes of signals S16 and S17.

### Modification 1 of Example 1

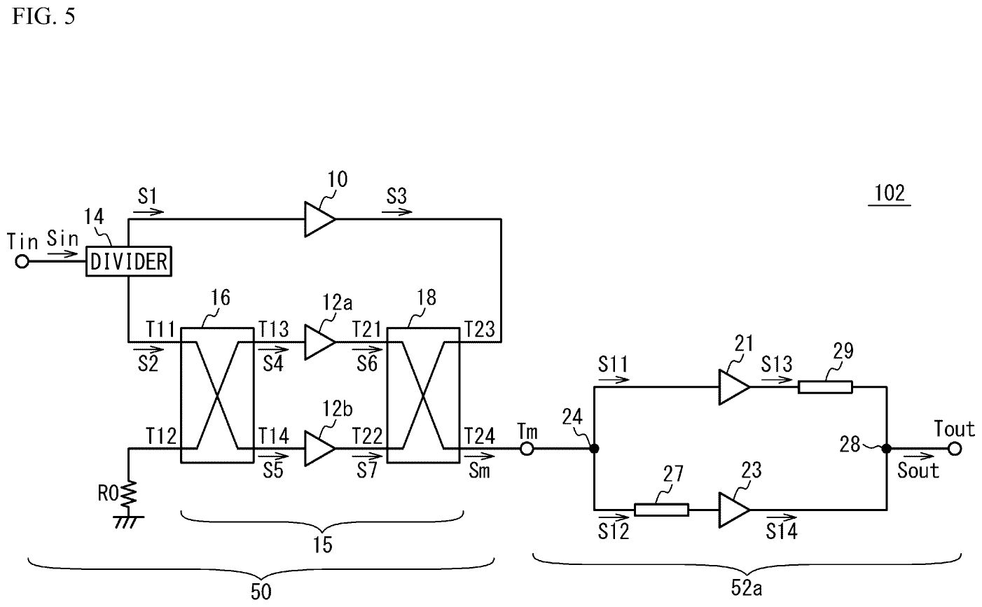

FIG. 5 is a block diagram of an amplifier according to a first modification of the first embodiment. As illustrated in FIG. 5, in an amplifier 102 of the first modification of the first embodiment, a Doherty amplifier circuit is used as a power amplifier circuit 52a. In power amplifier circuit 52a, divider 24 divides intermediate signal Sm into signals S11 and S12. A main amplifier 21 amplifies signal S11 and outputs the amplified signal as signal S13. A peak amplifier 23 amplifies signal S12 that has passed through a phase regulator 27, and outputs the amplified signal as signal S14. Coupler 28 combines signal S13 that have passed through an impedance converter 29 and signal S14, and outputs the combined signal to output terminal Tout as output signal Sout.

Main amplifier 21 is a class-A amplifier or a class-AB amplifier. Peak amplifier 23 is a class-C amplifier. When the power of intermediate signal Sm is small, main amplifier 21 operates and peak amplifier 23 does not operate. When the power of intermediate signal Sm is large, main amplifier 21 and peak amplifier 23 operate. By providing impedance converter 29, the load impedance seen from coupler 28 toward output terminal Tout when peak amplifier 23 operates and the load impedance seen from coupler 28 toward output terminal Tout when peak amplifier 23 does not operate can be equal to each other.

As in the first embodiment and its first modification, control amplifier 20 or main amplifier 21 that performs class-A or class-AB operation and balance amplifier 25 or peak amplifier 23 that performs class-C operation are used for power amplifier circuit 52 or 52a. This makes it possible to increase the efficiency in the power range from the power of intermediate signal Sm at which control amplifier 20 or main amplifier 21 reaches saturation power to the power of intermediate signal Sm at which balance amplifier 25 or peak amplifier 23 reaches saturation power.

### First Comparative Example

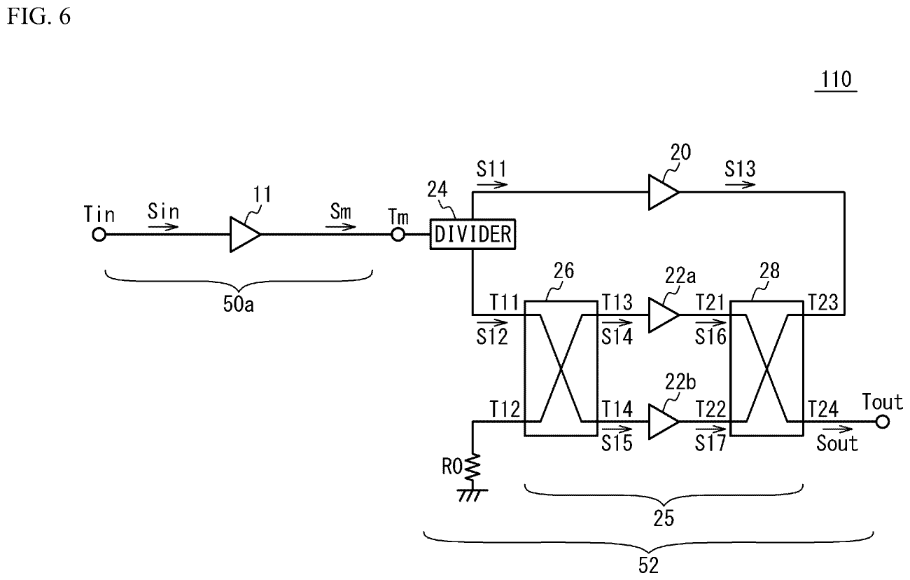

FIG. 6 is a block diagram of an amplifier according to a first comparative example. As illustrated in FIG. 6, in an amplifier 110 of the first comparative example, a driver amplifier circuit 50a is a single amplifier 11 without a balance amplifier. The other configurations are the same as those of the first embodiment.

As in power amplifier circuits 52 and 52a, if balance amplifier 25 or peak amplifier 23 operates or does not operate depending on the magnitude of intermediate signal Sm, the impedance seen from intermediate terminal Tm toward power amplifier circuits 52 and 52a changes. This changes the load impedance of driver amplifier circuit 50a. Thus, when the power of input signal Sin changes, the load impedance of amplifier 11 changes from the optimum impedance matching condition. When the operation band is narrow, the impedance matching condition may be maintained even if the load impedance of amplifier 11 varies. However, when the operation band is widened, if the load impedance of amplifier 11 varies, it is difficult to prevent the characteristics from deteriorating in a wide band. Further, when amplifier 11 is operated in class-A operation in order to improve linearity, efficiency is reduced.

### Second Comparative Example

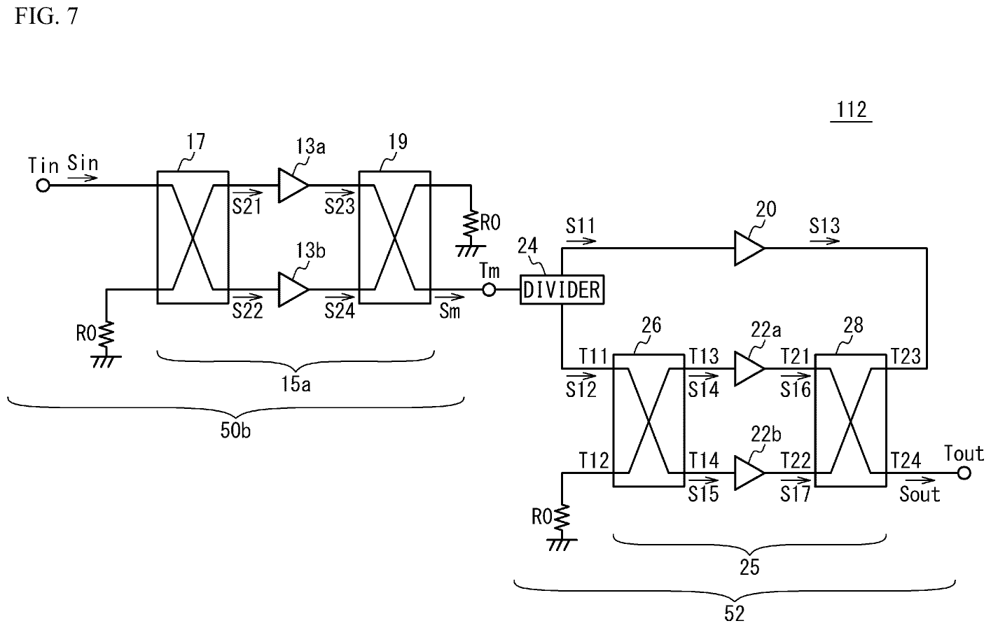

FIG. 7 is a block diagram of an amplifier according to a second comparative example. As illustrated in FIG. 7, in an amplifier 112 of the second comparative example, a driver amplifier circuit 50b is a balance amplifier 15a. Balance amplifier 15a includes a divider 17, a coupler 19, and amplifiers 13a and 13b. Divider 17 and coupler 19 are, for example, the branch line coupler illustrated in FIG. 3. In the branch line coupler, impedances seen from amplifiers 13a and 13b toward coupler 19 change gradually even when an impedance seen from intermediate terminal Tm toward power amplifier circuit 52 changes. For example, the impedances seen from amplifiers 13a and 13b toward coupler 19 can be a value close to the characteristic impedance of transmission line TL0 illustrated in FIG. 3. Thus, even when the power of input signal Sin changes, the load impedances of amplifiers 13a and 13b can be set to values close to the optimum impedance matching condition.

However, when amplifiers 13a and 13b are operated in class-A operation to improve linearity, efficiency is reduced.

### Description of First Embodiment and Its Modification 1

According to the first embodiment and its first modification, driver amplifier circuit 50 is an LMBA, and a branch line coupler as illustrated in FIG. 3, for example, is used as coupler 18. The branch line coupler includes end T21 (first end) to which signal S6 is input, end T22 (second end) to which signal S7 is input, end T23 (third end) to which signal S3 is input, and end T24 (fourth end) from which output signal Sout is output. Thus, the load impedances of auxiliary amplifiers 12a and 12b (impedances Z3a and Z3b in FIG. 4) change gradually even when the impedance seen from intermediate terminal Tm toward power amplifier circuit 52 changes. The load impedance of control amplifier 10 (impedance Z2 in FIG. 4) is the characteristic impedance of transmission line TL0 of the branch line coupler, and does not vary with the impedance seen from intermediate terminal Tm toward power amplifier circuit 52. In this way, the tolerance to load variation seen from driver amplifier circuit 50 toward power amplifier circuit 52 can be increased.

Since the load impedance of control amplifier 10 does not change with the power of input signal Sin, the efficiency of control amplifier 10 can be increased by making matching network 33 (see FIG. 2) perform efficiency matching. Further, the load impedance of auxiliary amplifiers 12a and 12b can be modulated by the power of signal S3. This allows the load impedances of auxiliary amplifiers 12a and 12b to be maintained close to efficient matching even when the power of signals S6 and S7 changes. This can increase the efficiency compared to the first and second comparative examples.

Control amplifier 10 may be an amplifier that performs class-A or class-AB operation, and auxiliary amplifiers 12a and 12b may be amplifiers that perform class-C operation. This can increase the efficiency. However, since the class-C amplifier is used, linearity and gain are deteriorated. Thus, control amplifier 10 and auxiliary amplifiers 12a and 12b are set to be amplifiers that perform class-A or class-AB operation. This improves linearity and gain.

In order to operate auxiliary amplifiers 12a and 12b as the balance amplifier 15, input bias voltages VG2 of auxiliary amplifier 12a and input bias voltage VG3 of auxiliary amplifier 12b are equal to each other. Input bias voltage VG1 of control amplifier 10 may be equal to input bias voltages VG2 and VG3 of auxiliary amplifiers 12a and 12b. The number of bias voltages can be reduced by making input bias voltage VG1 of control amplifier 10 equal to input bias voltages VG2 and VG3 of auxiliary amplifiers 12a and 12b. “Input bias voltages VG1, VG2, and VG3 are mutually equal” do not have to be exactly the same as each other. For example, when the maximum values of input bias voltages VG1, VG2, and VG3 are Vmax and the minimum values thereof are Vmin, (Vmax−Vmin)/(Vmax+Vmin)≤0.05 can be satisfied.

Power amplifier circuits 52 and 52a do not have to be LMBA or Doherty amplifier circuits, but may be amplifier circuits in which the impedance seen from intermediate terminal Tm toward power amplifier circuits 52 and 52a varies depending on the power of intermediate signal Sm. As described above, the amplifier circuit is an amplifier circuit including a first amplifier that performs class-A or class-AB operation and a second amplifier that is connected in parallel to the first amplifier and performs class-C operation. In the first embodiment and its first modification, even when the impedance seen from intermediate terminal Tm toward power amplifier circuits 52 and 52a varies, the tolerance for the load variation can be improved.

In the first embodiment and its first modification, the number of matching networks is four, i.e., matching networks 30 to 33. In the second comparative example, the number of matching networks is also four, i.e., an input matching network and an output matching network of amplifier 13a and an input matching network and an output matching network of amplifier 13b. Since the area of the matching network is large, the area is not so different between the first comparative example and the first embodiment and its first modification, and the size can be reduced to about the size of the second comparative example.

Table 1 illustrates the characteristics and sizes of driver amplifier circuits 50a (first comparative example), 50b (second comparative example), and 50 (first embodiment). In driver amplifier circuit 50, class-C indicates a case where auxiliary amplifiers 12a and 12b are class-C, and class-AB indicates a case where auxiliary amplifiers 12a and 12b are class-AB. Control amplifier 10 is class-AB in both cases. The characteristics are load variation tolerance, efficiency, linearity, and gain. The load variation tolerance indicates whether or not the characteristics are unlikely to change when the impedance seen from intermediate terminal Tm toward power amplifier circuit 52 varies. The characteristic and the size are ranked as A to D. A indicates that the characteristic or the size is the best, B indicates that the characteristic or the size is good but worse than the characteristic or the size that A indicates, C indicates that the characteristic or the size is better than the characteristic or the size that D indicates but worse than the characteristic or the size that B indicates, and D indicates that the characteristic or the size is worse than the characteristic or the size that C indicates.

TABLE 1

| DRIVER AMPLIFIER | | | 50 | |
|---|---|---|---|---|
| CIRCUIT | 50a | 50b | CLASS-C | CLASS-AB |
| LOAD VARIATION | C | B | B | B |
| TOLERANCE | | | | |
| EFFICIENCY | C | C | A | B |
| LINEARITY AND GAIN | B | B | D | B |
| SIZE | A | B | B | B |

Referring to Table 1, in driver amplifier circuit 50a of the first comparative example, one amplifier 11 is used. The linearity and gain are good and ranked as B The size is good and ranked as A. The load variation tolerance and efficiency are bad and ranked as C. In driver amplifier circuit 50b of the second comparative example, balance amplifier 15a is used. Thus, a hybrid coupler, such as a branch line coupler, is used as coupler 19. As a result, the load variation tolerance is good and ranked as B. The efficiency is ranked as C, which is the same rank as that of the efficiency of the first comparative example. Since amplifiers 13a and 13b, divider 17, and coupler 19 are used, the size is larger than that of the first comparative example and is ranked as B.

In driver amplifier circuit 50 of the first embodiment, the LMBA is used. Since a hybrid coupler is used as coupler 18, the load variation tolerance is ranked as B and is equivalent to that of the second comparative example. The efficiency is very good and ranked as A. However, when auxiliary amplifiers 12a and 12b are class-C amplifiers, the linearity and gain are deteriorated and ranked as D. Since the number of matching networks can be the same as that of the second comparative example, the size is ranked as B and is substantially the same as that of the second comparative example.

In driver amplifier circuit 50 of the first embodiment, when auxiliary amplifiers 12a and 12b are class-AB amplifiers, the efficiency is ranked as B, which is slightly inferior to that when auxiliary amplifiers 12a and 12b are class-C amplifiers. However, the linearity and gain can be good and can be ranked as B.

The embodiments disclosed herein are to be considered in all respects as illustrative and not restrictive. The scope of the present disclosure is defined by the appended claims rather than the foregoing description, and is intended to include all modifications within the scope and meaning equivalent to the claims.

1. An amplifier comprising:
a first amplifier circuit; and
a second amplifier circuit that amplifies an output signal of the first amplifier circuit, wherein
the first amplifier circuit includes:
a first divider that divides an input signal into a first signal and a second signal;
a control amplifier that amplifies the first signal and outputs an amplified signal as a third signal;
a second divider that divides the second signal into a fourth signal and a fifth signal having different phases at a center frequency of an operation band;
a first auxiliary amplifier that amplifies the fourth signal and outputs an amplified signal as a sixth signal;
a second auxiliary amplifier that amplifies the fifth signal and outputs an amplified signal as a seventh signal; and
a hybrid coupler including a first end that receives the sixth signal, a second end that receives the seventh signal, a third end that receives the third signal, and a fourth end that outputs the output signal.

2. The amplifier according to claim 1, wherein the control amplifier, the first auxiliary amplifier, and the second auxiliary amplifier perform class-A or class-AB operation.

3. The amplifier according to claim 1, wherein the control amplifier, the first auxiliary amplifier, and the second auxiliary amplifier have a mutually equal input bias voltage.

4. The amplifier according to claim 1, wherein the second amplifier circuit includes a first amplifier that perform class-A or class-AB operation and a second amplifier connected in parallel to the first amplifier and that perform class-C operation.

5. The amplifier according to claim 1, wherein the second amplifier circuit is a load modulated balanced amplifier (LMBA) or a Doherty amplifier circuit.

6. The amplifier according to claim 1, wherein
the control amplifier, the first auxiliary amplifier, and the second auxiliary amplifier perform class-A or class-AB operation, and
the second amplifier circuit is a load modulated balanced amplifier (LMBA) or a Doherty amplifier circuit.

7. The amplifier according to claim 1, wherein the hybrid coupler is a branch line coupler.

8. A driver amplifier circuit comprising:
a first divider that divides an input signal into a first signal and a second signal;
a control amplifier that amplifies the first signal and outputs an amplified signal as a third signal;
a second divider that divides the second signal into a fourth signal and a fifth signal having different phases at a center frequency of an operation band;
a first auxiliary amplifier that amplifies the fourth signal and outputs an amplified signal as a sixth signal;
a second auxiliary amplifier that amplifies the fifth signal and outputs an amplified signal as a seventh signal; and
a hybrid coupler including a first end that receives the sixth signal, a second end that receives the seventh signal, a third end that receives the third signal, and a fourth end that outputs an output signal to a subsequent-stage amplifier circuit.

9. The driver amplifier circuit according to claim 8, wherein the control amplifier, the first auxiliary amplifier, and the second auxiliary amplifier perform class-A or class-AB operation.

10. The driver amplifier circuit according to claim 8, wherein the control amplifier, the first auxiliary amplifier, and the second auxiliary amplifier have a mutually equal input bias voltage.
